(19) United States
(12) Patent Application Publication
(10) Pub. No.: US 2016/0005868 A1
(43) Pub. Date: Jan. 7, 2016

(54) FINFET WITH CONFINED EPITAXY

(71) Applicant: GLOBALFOUNDRIES Inc., Grand Cayman (KY)

(72) Inventors: Andy Chih-Hung Wei, Queensbury, NY (US); Jing Wan, Malta, NY (US); Dae-Han Choi, Loudonville, NY (US)

(21) Appl. No.: 14/320,932

(22) Filed: Jul. 1, 2014

(51) Int. Cl. H01L 29/78; H01L 21/306; H01L 29/10; H01L 29/66

(52) U.S. Cl. CPC H01L 29/7853; H01L 29/66795; H01L 21/30604; H01L 29/1033

(57) ABSTRACT

Embodiments of the present invention provide a fin-type field effect transistor (finFET) with confined epitaxy. A protective layer is formed on a fin. The protective layer is recessed to expose the fin top. A fin cavity is formed in the fin. An epitaxial region is formed in the fin cavity. The epitaxial region has a confined portion and a diamond-shaped portion, resulting in increased epitaxial volume. The increased epitaxial volume can result in enhanced carrier mobility and improved device performance.

### BACKGROUND

As integrated circuits continue to scale downward in size, the finFET (fin field effect transistor) is becoming attractive for use with modern semiconductor devices. In a finFET, the channel is formed by a semiconductor vertical fin, and a gate electrode is located and wrapped around the vertical fin. Maintaining carrier mobility in the channel of finFETs is an important factor in device operation. Stressor regions can be used to improve carrier mobility in order to achieve an improvement regarding the speed of device operation. However, the reduced critical dimensions of current technology nodes pose a variety of challenges in the use of such stressor regions. It is therefore desirable to have improved methods and structures to improve finFET performance.

### SUMMARY

Embodiments of the present invention provide a fin-type field effect transistor (finFET) with confined epitaxy. A protective layer is formed on a fin. The protective layer is recessed to expose the fin top. A fin cavity is formed in the fin. An epitaxial region is formed in the fin cavity. The epitaxial region has a confined portion and a generally diamond-shaped portion, resulting in increased epitaxial volume. The increased epitaxial volume can result in enhanced carrier mobility and improved device performance.

In a first aspect, embodiments of the present invention provide a method of forming a semiconductor structure comprising: forming a fin on a semiconductor substrate; forming a shallow trench isolation layer on the semiconductor substrate, wherein the shallow trench isolation layer is adjacent with a lower section of the fin; depositing a protective layer on the fin; removing a portion of the protective layer such that a top portion of the fin is exposed while sidewalls of the fin remain covered; forming a fin cavity in the fin; and depositing a semiconductor material in the fin cavity.

In a second aspect, embodiments of the present invention provide a semiconductor structure comprising: a semiconductor substrate comprised of a substrate material; a fin formed on the semiconductor substrate, wherein the fin comprises a lower section and an upper section, wherein the lower section is comprised of the substrate material, and wherein the upper section is comprised of a second semiconductor material and includes a generally diamond-shaped region disposed on a top portion of the upper section; a shallow trench isolation layer disposed on the semiconductor substrate and in contact with the lower section of the fin; and a protective layer disposed on the shallow trench isolation layer and sidewalls of the upper section.

In a third aspect, embodiments of the present invention provide a semiconductor structure comprising: a semiconductor substrate comprised of a substrate material; a first fin formed on the semiconductor substrate, wherein the first fin comprises a lower section and an upper section, wherein the lower section is comprised of the substrate material, and wherein the upper section is comprised of a second semiconductor material and includes a generally diamond-shaped region disposed on a top portion of the upper section; a second fin formed on the semiconductor substrate, wherein the second fin comprises a lower section and an upper section, wherein the lower section is comprised of the substrate material, and wherein the upper section is comprised of a third semiconductor material and includes a generally diamond-shaped region disposed on a top portion of the upper section; a shallow trench isolation layer disposed on the semiconductor substrate and in contact with the lower section of the first fin and second fin; and a protective layer disposed on the shallow trench isolation layer and sidewalls of the upper section of the first fin and sidewalls of the upper section of the second fin.

### BRIEF DESCRIPTION OF THE DRAWINGS

These and other features of this invention will be more readily understood from the following detailed description of the various aspects of the invention taken in conjunction with the accompanying drawings in which:

FIG. 1 is a top-down view of a semiconductor structure at a starting point for embodiments of the present invention.

FIG. 2A and FIG. 2B show side views of a semiconductor structure at a starting point for embodiments of the present invention.

FIG. 3 is a semiconductor structure after a subsequent process step of depositing a mask over the semiconductor structure.

FIG. 4 is a semiconductor structure after a subsequent process step of removing a portion of the mask over a fin.

FIG. 5 is a semiconductor structure after a subsequent process step of exposing the fin top in accordance with illustrative embodiments.

FIG. 6 is a semiconductor structure after a subsequent process step of forming a fin cavity in accordance with illustrative embodiments.

FIG. 7 is a semiconductor structure after a subsequent process step of forming a sigma fin cavity in accordance with illustrative embodiments.

FIG. 8 is a semiconductor structure after a subsequent process step of filling the fin cavity.

FIG. 9 is a semiconductor structure after a subsequent process step of filling a second fin cavity in accordance with illustrative embodiments.

FIG. 10 is a semiconductor structure after a subsequent process step of filling a second fin cavity in accordance with alternative illustrative embodiments.

FIG. 11 is a flowchart indicating process steps for embodiments of the present invention.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Furthermore, for clarity, some reference numbers may be omitted in certain drawings.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art.

The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof. The term “include” shall have the same meaning as “comprise” when used herein.

Reference throughout this specification to “one embodiment,” “an embodiment,” “embodiments,” “exemplary embodiments,” “some embodiments,” or similar language means that a particular feature, structure, or characteristic described in connection with the embodiment is included in at least one embodiment of the present invention. Thus, appearances of the phrases “in one embodiment,” “in an embodiment,” “in some embodiments,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

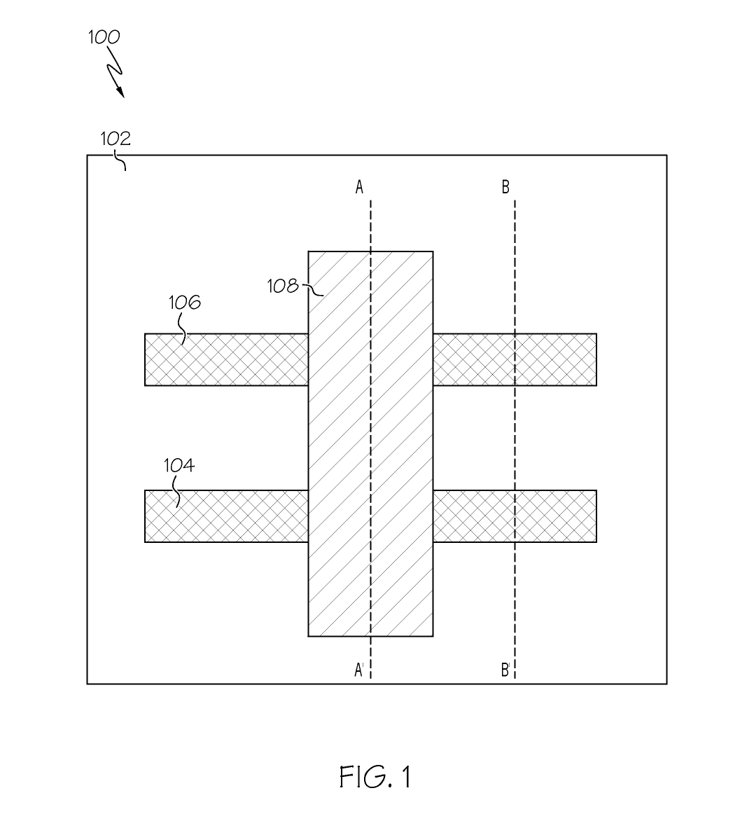

FIG. 1 is a top-down view of a semiconductor structure 100 indicating a semiconductor substrate 102. A first fin 104 and second fin 106 are disposed on semiconductor substrate 102. A gate structure 108 is disposed over the first fin 104 and second fin 106. Using line A-A′ and line B-B′, FIG. 1 serves as a perspective reference for subsequent figures.

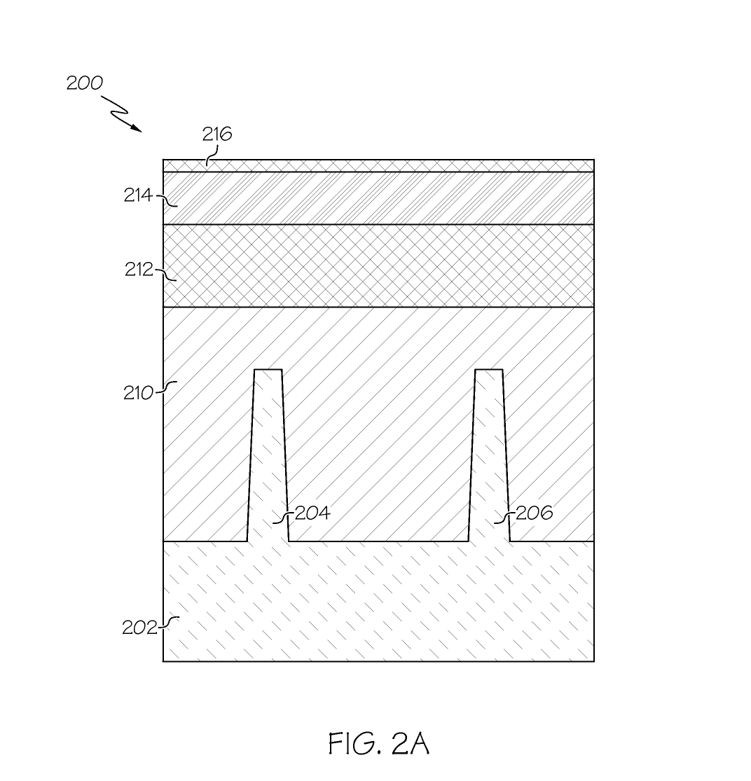

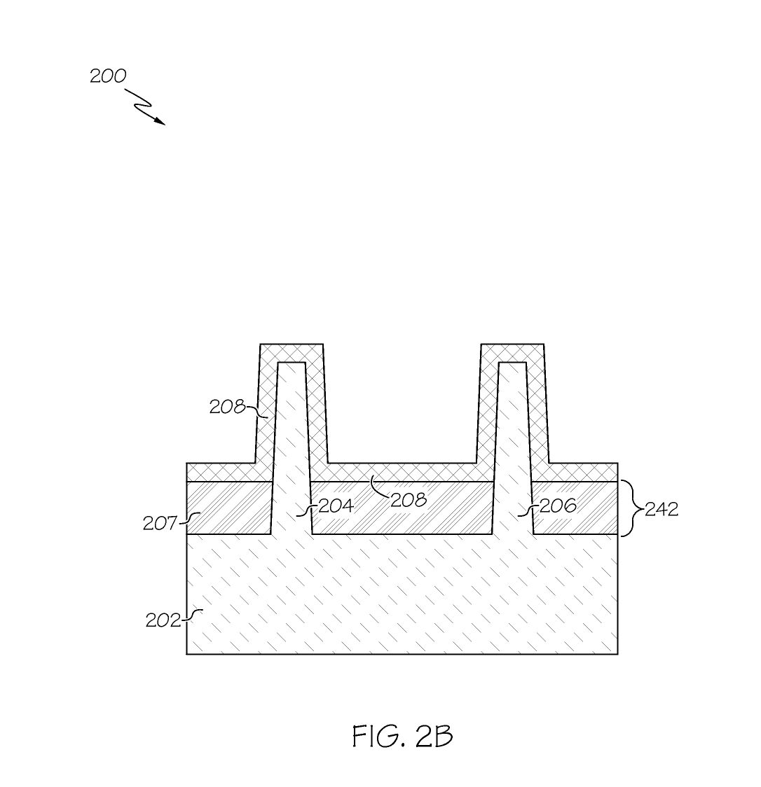

FIG. 2A is a side view of a semiconductor structure 200 at a starting point for embodiments of the present invention, as viewed along line A - A′ of FIG. 1. Semiconductor structure 200 comprises semiconductor substrate 202. In embodiments, the substrate material for semiconductor substrate 202 comprises silicon. Fins 204 and 206 are formed on the semiconductor substrate 202. The fins 204 and 206 may also be comprised of silicon. A dummy gate 210 is formed over the fins 204 and 206. In embodiments, dummy gate 210 may comprise amorphous silicon or polysilicon. A silicon nitride layer 212 is disposed on the dummy gate 210. A silicon oxide layer 214 is disposed on silicon nitride layer 212. Another silicon nitride layer 216 is disposed on the silicon oxide layer 214.

FIG. 2B is a side view of a semiconductor structure 200 at a starting point for embodiments of the present invention, as viewed along line B-B′ of FIG. 1. A shallow trench isolation layer 207 is disposed on the semiconductor substrate 202, and is disposed between the fins 204 and 206 such that shallow trench isolation layer 207 is adjacent to, and in contact with, a lower section 242 of the fins 204 and 206. A protective layer 208 is disposed on the fin 204 and fin 206. In embodiments, the protective layer 208 comprises silicon nitride. Protective layer 208 serves to protect the fins and shallow trench isolation layer 207 during subsequent process steps.

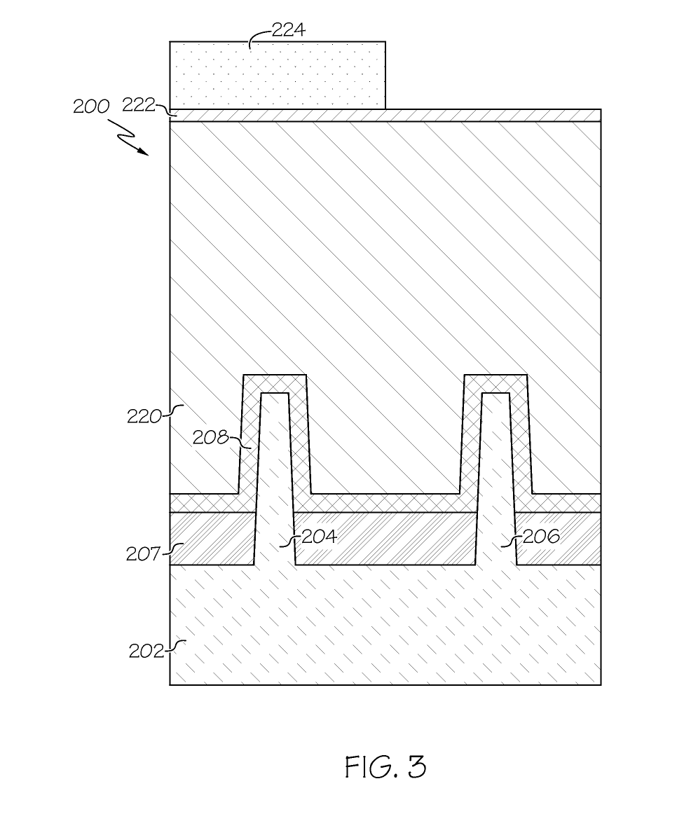

FIG. 3 is semiconductor structure 200 after a subsequent process step of depositing a mask over the semiconductor structure. An organic planarization layer (OPL) 220 is deposited on the semiconductor structure 200. In embodiments, the OPL 220 may include a photo-sensitive organic polymer comprising a light-sensitive material that, when exposed to electromagnetic radiation, is chemically altered, and thus configured to be removed using a developing solvent. For example, the photo-sensitive organic polymer may be polyacrylate resin, epoxy resin, phenol resin, polyamide resin, polyimide resin, unsaturated polyester resin, polyphenylenether resin, polyphenylenesulfide resin, or benzocyclobutene (BCB). A silicon containing anti-reflective coating (SiARC) 222 is deposited on the OPL 220. A photoresist layer 224 is deposited on the SiARC 222, and then patterned such that it remains over fin 204, but is not over fin 206.

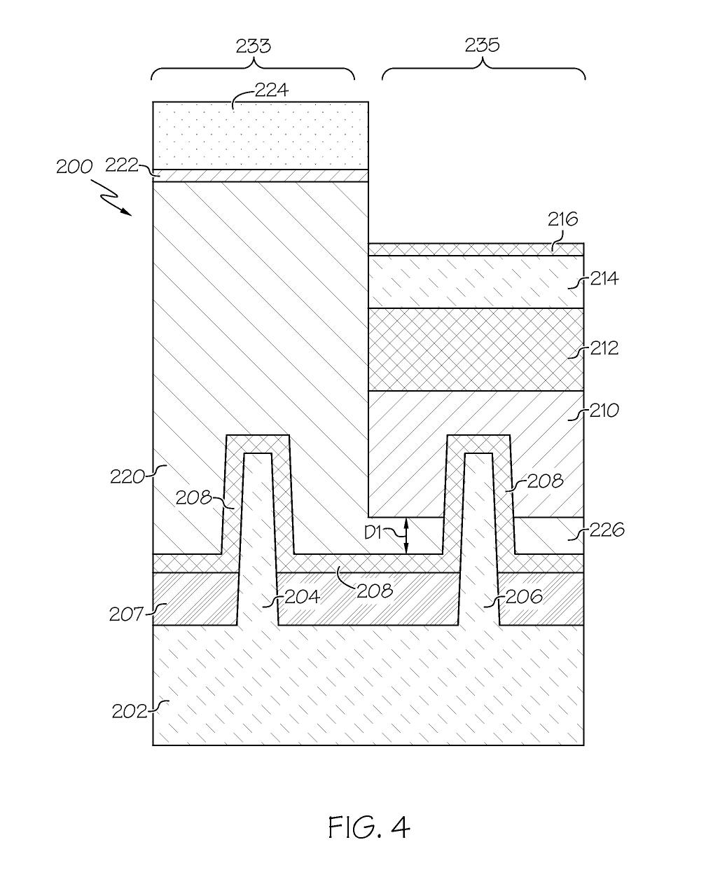

FIG. 4 is semiconductor structure 200 after a subsequent process step of removing a portion of the mask over region 235, while the OPL 220 is preserved in region 233. As a result, a portion of the protective layer 208 covering fin 206 is exposed. In embodiments, the OPL is not completely removed from the region 235, such that a portion 226 of the OPL remains in region 235. The remaining OPL portion has a thickness D1. In embodiments, D1 ranges from about 10 nanometers to about 20 nanometers. The OPL region 226 provides protection for protective layer 208 during subsequent processing.

FIGS. 4-10 show composite side views, where features along line A-A′ of FIG. 1 and features along line B-B′ of FIG. 1 are shown together. For example, protective layer 208 is shown as viewed along line B-B′ of FIG. 1, while dummy gate 210 and layers 212, 214, and 216 are shown as viewed along line A-A′ of FIG. 1.

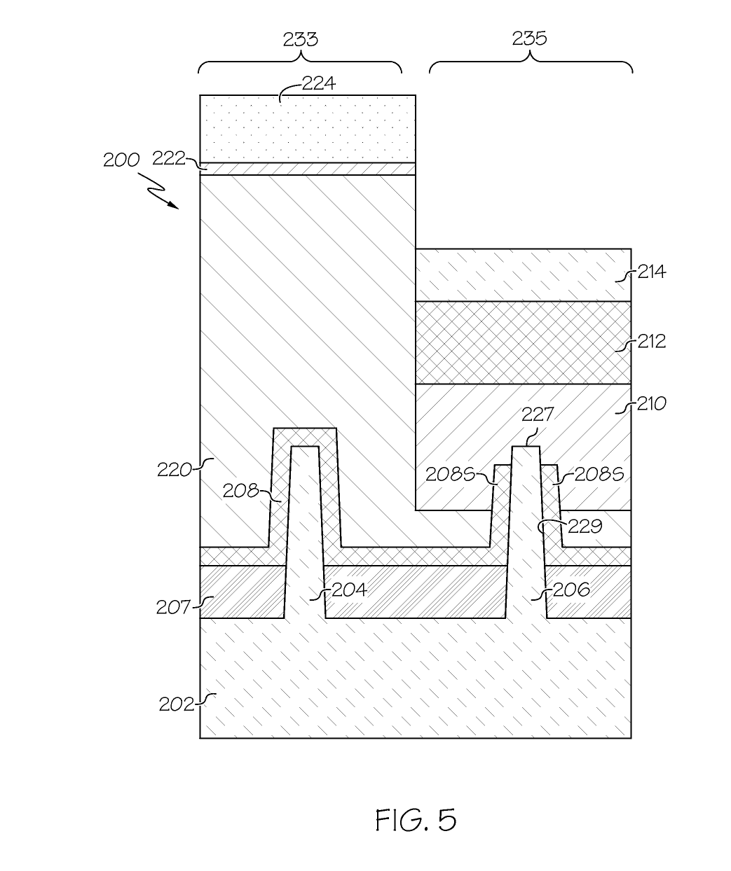

FIG. 5 is semiconductor structure 200 after a subsequent process step of exposing the fin top in accordance with illustrative embodiments. The protective layer 208 (e.g. silicon nitride layer) is recessed to expose top portion 227 of fin 206, hence removing a portion of the protective layer such that a top portion 227 of the fin 206 is exposed while sidewalls 229 of the fin remain covered with protective layer regions 208S. In embodiments, the recess to expose top portion 227 is performed with a reactive ion etch process. As a result, top nitride layer 216 (see FIG. 4) is also removed in region 235.

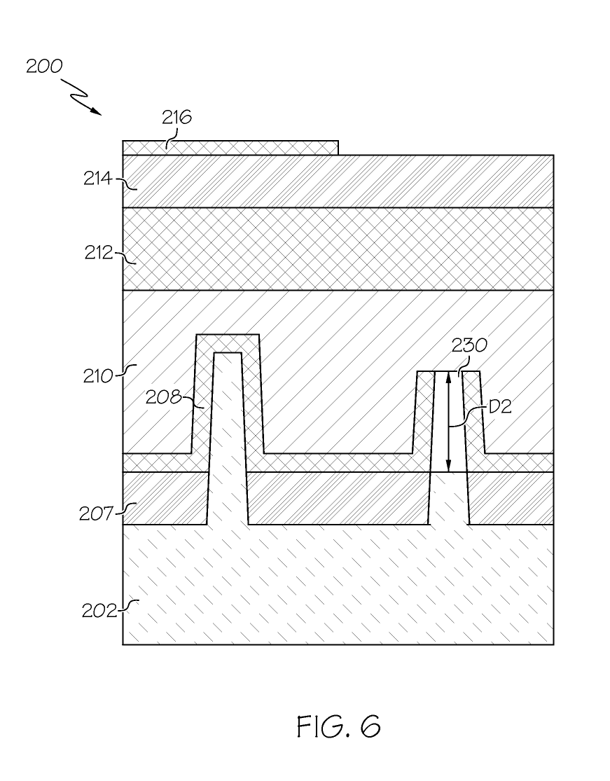

FIG. 6 is semiconductor structure 200 after a subsequent process step of forming a fin cavity 230 in accordance with illustrative embodiments. In embodiments, the fin cavity 230 is formed using a reactive ion etch process. In other embodiments, a selective wet or dry etch may be used to form cavity 230. The fin cavity 230 has a depth D2. In embodiments, depth D2 ranges from about 20 nanometers to about 30 nanometers. The OPL layer 220, SiARC layer 222, and photoresist layer 224 are then removed.

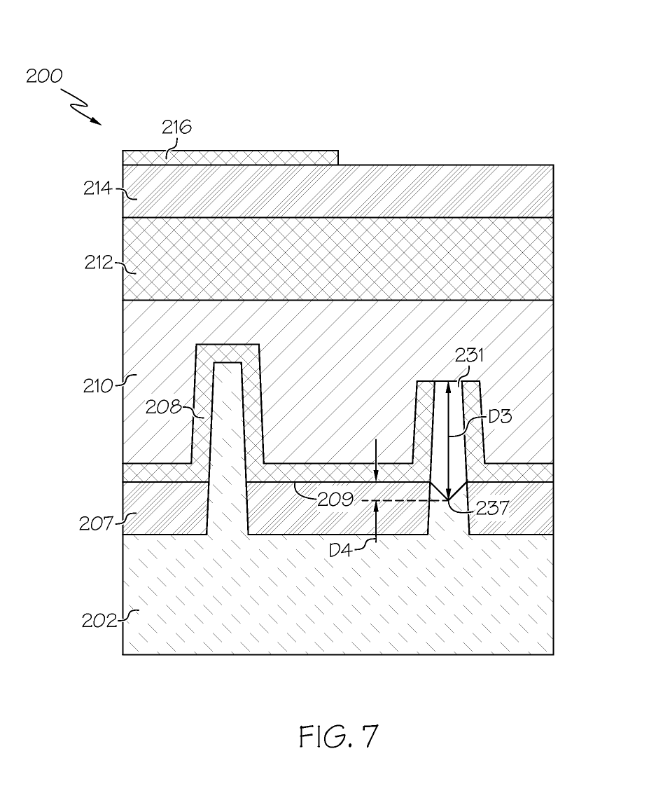

FIG. 7 is a semiconductor structure 200 after a subsequent optional process step of forming a sigma fin cavity 231 in accordance with illustrative embodiments. In embodiments, the sigma fin cavity 231 may be formed with a sigma etch that uses a tetramethylammonium hydroxide-based etch and/or an ammonia-based etch. The sigma fin cavity 231 may be formed as a single etch process, or as an additional etch process after forming a cavity 230 as shown in FIG. 6. The sigma fin cavity 231 has a depth D3. In embodiments, depth D3 ranges from about 25 nanometers to about 35 nanometers. The fin sigma cavity 231 has a sigma vertex 237 at its bottom. In embodiments, the sigma fin cavity 231 may extend to a depth D4 below a top surface 209 of the shallow trench isolation layer 207. In embodiments, depth D4 may range from about 5 nanometers to about 10 nanometers.

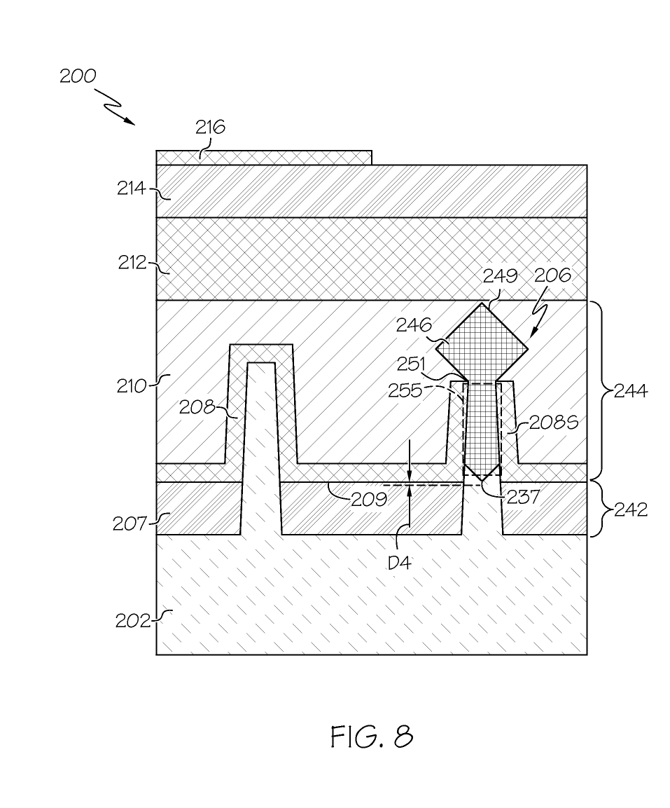

FIG. 8 is semiconductor structure 200 after a subsequent process step of filling the sigma fin cavity (231 of FIG. 7) with an epitaxial material 246. As a result, fin 206 comprises a lower section 242 comprised of silicon, and an upper section 244 comprised of epitaxial material 246. In embodiments, epitaxial material 246 may include silicon germanium, silicon phosphorus, or silicon carbon phosphorus. The epitaxial material 246 includes confined epitaxial region 255 which is confined by the sidewall portions 208S of the protective layer. Above the sidewall portions 208S, the epitaxial region 246 forms as a diamond-shaped region 249. Hence, the protective layer sidewall portions 208S are in contact with the diamond-shaped region 249 at the base 251 of the diamond-shaped region 249. The epitaxial material 246 may be deposited by a chemical vapor deposition (CVD) process, or other suitable process.

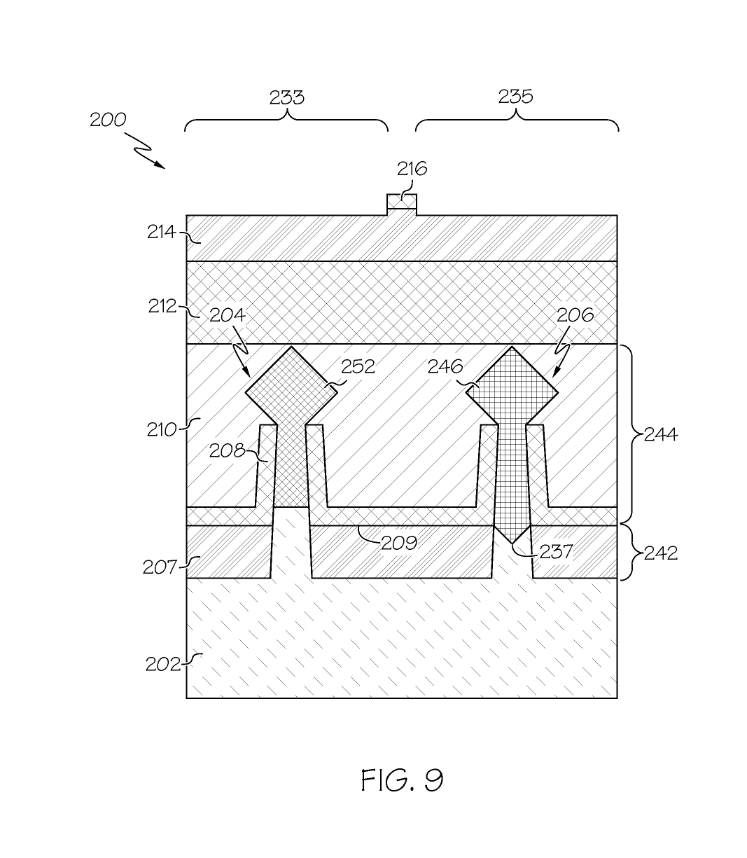

FIG. 9 is semiconductor structure 200 after a subsequent process step of filling a second fin cavity in accordance with illustrative embodiments. The aforementioned process shown in FIGS. 2A-FIG. 8 is repeated, this time using the OPL to protect fin 206 of region 235, while forming a fin cavity in fin 204 of region 233 and filling the cavity with epitaxial material 250. In a CMOS configuration, epitaxial region 246 may be comprised of silicon germanium for a P-type finFET, while epitaxial region 250 may be comprised of silicon phosphorus or silicon carbon phosphorus. One or more of the fins may have an upper section 244 having a sigma shape. As shown in FIG. 9, epitaxial region 246 has the sigma shape with sigma vertex 237, while epitaxial region 250 is not of a sigma shape. A small portion of silicon nitride layer 216 may remain on the top of structure 200, which can be removed via etch or planarization in a subsequent process step.

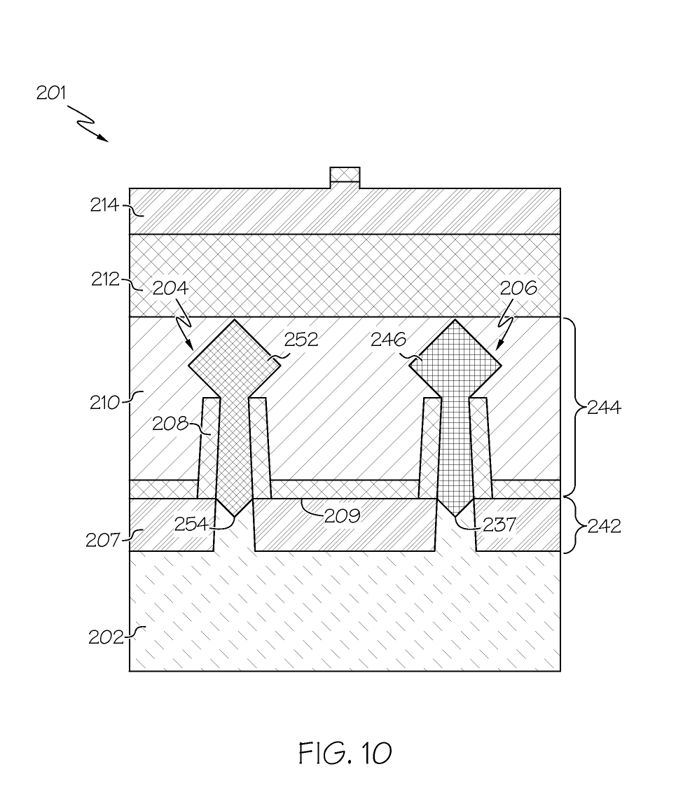

FIG. 10 is a semiconductor structure 201 after a subsequent process step of filling a second fin cavity in accordance with alternative illustrative embodiments. Semiconductor structure 201 is similar to semiconductor structure 200 as shown in FIG. 9, except that both fins have a sigma shape in the upper section 244. Epitaxial region 246 has sigma vertex 237, and epitaxial region 252 has sigma vertex 254.

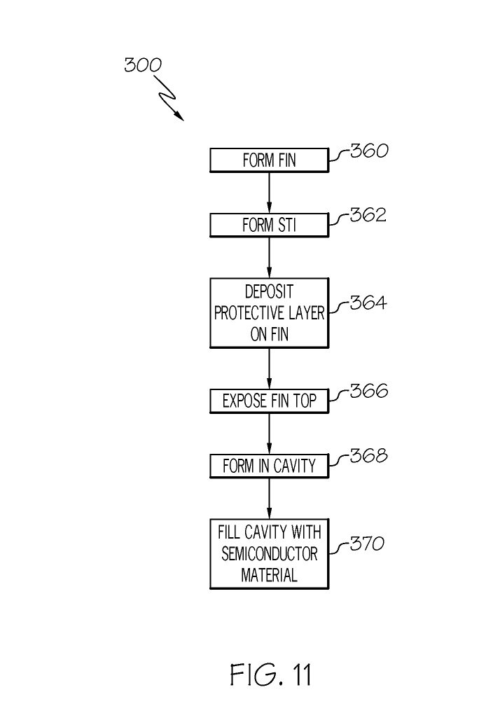

FIG. 11 is a flowchart 300 indicating process steps for embodiments of the present invention. In process step 360, a plurality of fins is formed. This may be accomplished using a sidewall image transfer (SIT) process or other suitable method. In process step 362, a shallow trench isolation (STI) region is formed. This may include depositing a silicon oxide layer. In embodiments, the STI may be deposited using a chemical vapor deposition (CVD) process. In process step 364, a protective layer is deposited on the fin. The protective layer may be a conformal layer and may be comprised of silicon nitride. In process step 366, the top of a fin is exposed. This may be performed by recessing the protective layer. In embodiments, a selective etch, such as a selective reactive ion etch, process is used to expose the fin top, while leaving the fin sidewalls covered by the protective layer. In process step 368, a fin cavity is formed. The fin cavity may be a sigma cavity in some embodiments. In process step 370, the fin cavity is filled with an epitaxial semiconductor material. The epitaxial semiconductor material is confined by the protective layer, except at the top, where a diamond-shaped region is formed. The process shown in flowchart 300 may be repeated to form different epitaxial semiconductor regions in adjacent fins to support CMOS devices. In such embodiments (as shown in FIGS. 9 and 10), a p-type finFET device utilizes one type of epitaxial semiconductor material, while an adjacent n-type finFET device utilizes a different type of epitaxial material. From this point forward, industry-standard techniques may be used to complete the fabrication of the integrated circuit. These techniques may include, but are not limited to, formation of metallization and via layers, additional dielectric layers, packaging, and test.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A method of forming a semiconductor structure comprising:
forming a fin on a semiconductor substrate;
forming a shallow trench isolation layer on the semiconductor substrate, wherein the shallow trench isolation layer is adjacent with a lower section of the fin;
depositing a protective layer on the fin;
removing a portion of the protective layer such that a top portion of the fin is exposed while sidewalls of the fin remain covered;
forming a fin cavity in the fin; and
depositing a semiconductor material in the fin cavity.

2. The method of claim 1, wherein depositing a protective layer on the fin comprises depositing a silicon nitride layer.

3. The method of claim 2, wherein removing a portion of the protective layer such that a top portion of the fin is exposed while sidewalls of the fin remain covered is performed with a reactive ion etch process.

4. The method of claim 1, wherein forming a fin cavity comprises performing a reactive ion etch.

5. The method of claim 1, wherein forming a fin cavity comprises performing a sigma etch.

6. The method of claim 5, wherein forming the fin cavity comprises forming the fin cavity to a depth below a top surface of the shallow trench isolation layer.

7. The method of claim 5, wherein the sigma etch comprises a tetramethylammonium hydroxide-based etch.

8. The method of claim 5, wherein the sigma etch comprises an ammonia-based etch.

9. The method of claim 1, wherein depositing a semiconductor material in the fin cavity comprises depositing silicon germanium.

10. The method of claim 1, wherein depositing a semiconductor material in the fin cavity comprises depositing silicon phosphorus.

11. The method of claim 1, wherein depositing a semiconductor material in the fin cavity comprises depositing silicon carbon phosphorus.

12. A semiconductor structure comprising:
a semiconductor substrate comprised of a substrate material;
a fin formed on the semiconductor substrate, wherein the fin comprises a lower section and an upper section, wherein the lower section is comprised of the substrate material, and wherein the upper section is comprised of a second semiconductor material and includes a generally diamond-shaped region disposed on a top portion of the upper section;
a shallow trench isolation layer disposed on the semiconductor substrate and in contact with the lower section of the fin; and
a protective layer disposed on the shallow trench isolation layer and sidewalls of the upper section.

13. The semiconductor structure of claim 12, wherein the protective layer is in contact with the diamond-shaped region.

14. The semiconductor structure of claim 12, wherein the protective layer is comprised of silicon nitride.

15. The semiconductor structure of claim 12, wherein the upper section includes a sigma vertex disposed on a bottom portion of the upper section.

16. The semiconductor structure of claim 12, wherein the second semiconductor material is comprised of material selected from the group consisting of silicon germanium, silicon phosphorus, and silicon carbon phosphorus.

17. A semiconductor structure comprising:
a semiconductor substrate comprised of a substrate material;
a first fin formed on the semiconductor substrate, wherein the first fin comprises a lower section and an upper section, wherein the lower section is comprised of the substrate material, and wherein the upper section is comprised of a second semiconductor material and includes a generally diamond-shaped region disposed on a top portion of the upper section;
a second fin formed on the semiconductor substrate, wherein the second fin comprises a lower section and an upper section, wherein the lower section is comprised of the substrate material, and wherein the upper section is comprised of a third semiconductor material and includes a generally diamond-shaped region disposed on a top portion of the upper section;
a shallow trench isolation layer disposed on the semiconductor substrate and in contact with the lower section of the first fin and second fin; and
a protective layer disposed on the shallow trench isolation layer and sidewalls of the upper section of the first fin and sidewalls of the upper section of the second fin.

18. The semiconductor structure of claim 17, wherein the second semiconductor material comprises silicon germanium, and wherein the third semiconductor material comprises silicon phosphorus.

19. The semiconductor structure of claim 17, wherein the upper section of the first fin includes a first sigma vertex disposed on a bottom portion of the upper section of the first fin, and wherein the upper section of the second fin includes a second sigma vertex disposed on a bottom portion of the upper section of the second fin.

20. The semiconductor structure of claim 19, wherein the first fin and second fin each include a confined epitaxial region.
